(19) United States
(12) Patent Application Publication
(10) Pub. No.: US 2016/0126013 A1
(43) Pub. Date: May 5, 2016

(54) MULTILAYER CERAMIC ELECTRONIC COMPONENT AND BOARD HAVING THE SAME

(71) Applicant: SAMSUNG ELECTRO-MECHANICS CO., LTD., Suwon-Si (KR)

(72) Inventors: Heung Kil PARK, Suwon-Si (KR); Kyoung Jin JUN, Suwon-Si (KR); Soon Ju LEE, Suwon-Si (KR); So Yeon SONG, Suwon-Si (KR)

(21) Appl. No.: 14/880,049

(22) Filed: Oct. 9, 2015

(30) Foreign Application Priority Data
Nov. 3, 2014 (KR) 10-2014-0151097

(51) Int. Cl. H01G 4/12; H01G 4/248; H01G 4/30; H01G 4/012; H05K 1/18; H05K 1/11

(52) U.S. Cl. CPC H01G 4/12; H05K 1/181; H05K 1/111; H01G 4/30; H01G 4/012; H01G 4/248; H05K 2201/10015

(57) ABSTRACT

A multilayer ceramic electronic component includes: a plurality of active parts disposed to be distinguishable from each other in a stacking direction, wherein internal electrodes of an upper active part include protrusion portions which correspond to band portions of external electrodes and extend in a width direction, and internal electrodes of a lower active part positioned to be adjacent to a mounting surface include recess portions which correspond to the band portions of the external electrodes and are recessed in the width direction.

### CROSS-REFERENCE TO RELATED APPLICATION

This application claims benefit of priority to Korean Patent Application No. 10-2014-0151097 filed on Nov. 3, 2014, with the Korean Intellectual Property Office, the disclosure of which is incorporated herein by reference.

### BACKGROUND

The present disclosure relates to a multilayer ceramic electronic component and a board having the same.

Electronic components which use ceramic materials include capacitors, inductors, piezoelectric elements, varistors, thermistors, and the like.

A multilayer ceramic capacitor (MLCC), one of these ceramic electronic components, may be used in various electronic apparatuses due to advantages such as a small size, high capacitance, and ease of mountability.

For example, the multilayer ceramic capacitor may be used as a chip type condenser mounted on boards of several electronic products such as display devices including liquid crystal displays (LCDs), plasma display panels (PDPs), and the like, computers, personal digital assistants (PDAs), and mobile phones, and the like, and serving to charge and discharge electricity.

This multilayer ceramic capacitor may have a structure in which a plurality of dielectric layers and internal electrodes disposed between the dielectric layers and having different polarities are alternately disposed.

In this case, since the dielectric layers have piezoelectric properties, when a direct current (DC) or alternating current (AC) voltage is applied to the multilayer ceramic capacitor, a piezoelectric phenomenon may occur between the internal electrodes to generate periodic vibrations while expanding and contracting a volume of a ceramic body depending on frequency.

These vibrations may be transferred to a board through external electrodes of the multilayer ceramic capacitor and solders connecting the external electrodes with the board, such that an entire board becomes a sound reflecting surface to transmit the sound of vibrations as noise.

The sound of vibrations may correspond to an audio frequency range of 20 Hz to 20,000 Hz potentially causing user discomfort. The vibration noise causing listener discomfort as described above is called acoustic noise.

Further, in modern electronic devices, silence of a mechanical component has been implemented, such that the acoustic noise generated in the multilayer ceramic capacitor as described above may become more prominent.

In a case in which the device is operated in a silent environment, the user may consider the acoustic noise as a fault of the device.

In addition, when audio output in a device having an audio circuit overlaps the acoustic noise, the quality of the device may be deteriorated.

### SUMMARY

An aspect of the present disclosure may provide a multilayer ceramic electronic component capable of reducing acoustic noise, and a board having the same.

According to an aspect of the present disclosure, a multilayer ceramic electronic component may include: a plurality of active parts disposed to be distinguishable from each other in a stacking direction, wherein internal electrodes of an upper active part include protrusion portions which correspond to band portions of external electrodes and extend in a width direction, and internal electrodes of a lower active part which is positioned to be adjacent to a mounting surface include recess portions which correspond to the band portions of the external electrodes and are recessed in the width direction.

According to another aspect of the present disclosure, a board having a multilayer ceramic electronic component may include: a circuit board on which a plurality of electrode pads are provided; and the multilayer ceramic electronic component as described above, mounted on the circuit board by allowing the band portions of the external electrodes to be connected to the electrode pads.

### BRIEF DESCRIPTION OF DRAWINGS

The above and other aspects, features and advantages of the present disclosure will be more clearly understood from the following detailed description taken in conjunction with the accompanying drawings, in which:

FIG. 1 is a perspective view schematically illustrating a multilayer ceramic electronic component according to an exemplary embodiment in the present disclosure;

FIG. 2 is a cross-sectional view taken along line A-A′ of FIG. 1;

FIG. 3 is an exploded perspective view illustrating examples of first and second internal electrodes of the multilayer ceramic electronic component of FIG. 1;

FIG. 4 is an exploded perspective view illustrating examples of third and fourth internal electrodes of the multilayer ceramic electronic component of FIG. 1;

FIG. 5 is an exploded perspective view illustrating other examples of the first and second internal electrodes of the multilayer ceramic electronic component of FIG. 1;

FIG. 6 is a perspective view illustrating a structure in which an insulating layer is disposed in the multilayer ceramic electronic component of FIG. 1;

FIG. 7 is a cross-sectional view taken along line B-B′ of FIG. 6;

FIG. 8 is a perspective view schematically illustrating a multilayer ceramic electronic component according to another exemplary embodiment in the present disclosure;

FIG. 9 is a perspective view illustrating a structure in which an insulating layer is disposed in the multilayer ceramic electronic component of FIG. 8;

FIG. 10 is a cross-sectional view illustrating a board in which the multilayer ceramic electronic component of FIG. 1 is mounted on a circuit board; and

FIG. 11 is a cross-sectional view illustrating a board in which the multilayer ceramic electronic component of FIG. 6 is mounted on a circuit board.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

### Multilayer Ceramic Electronic Component

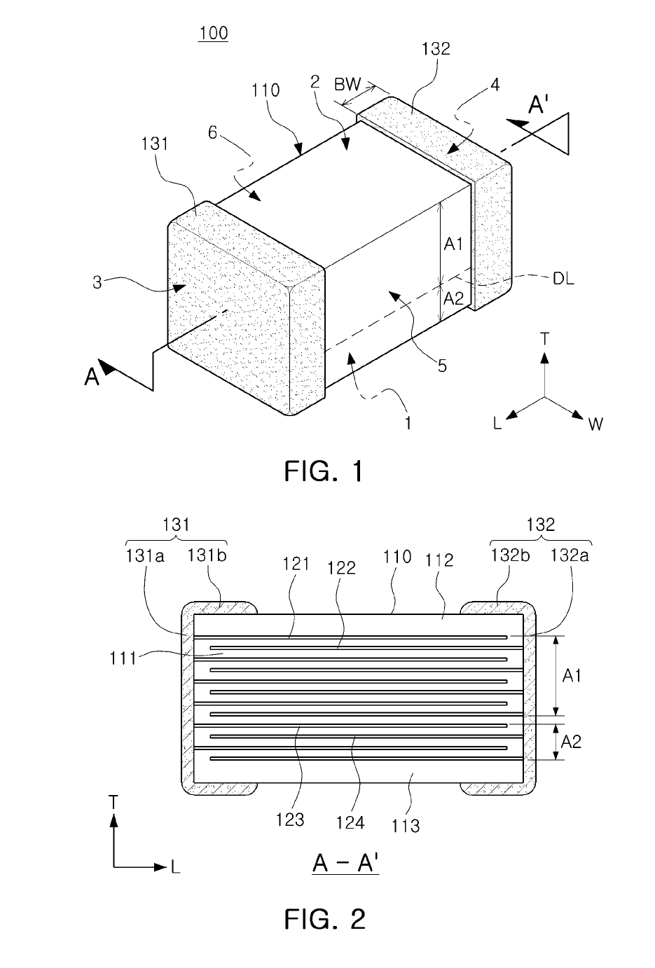

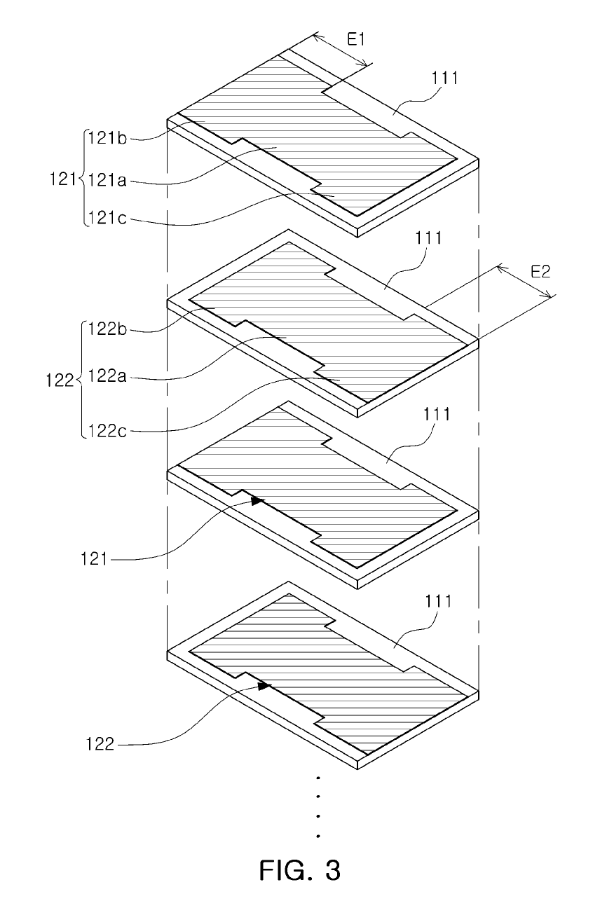

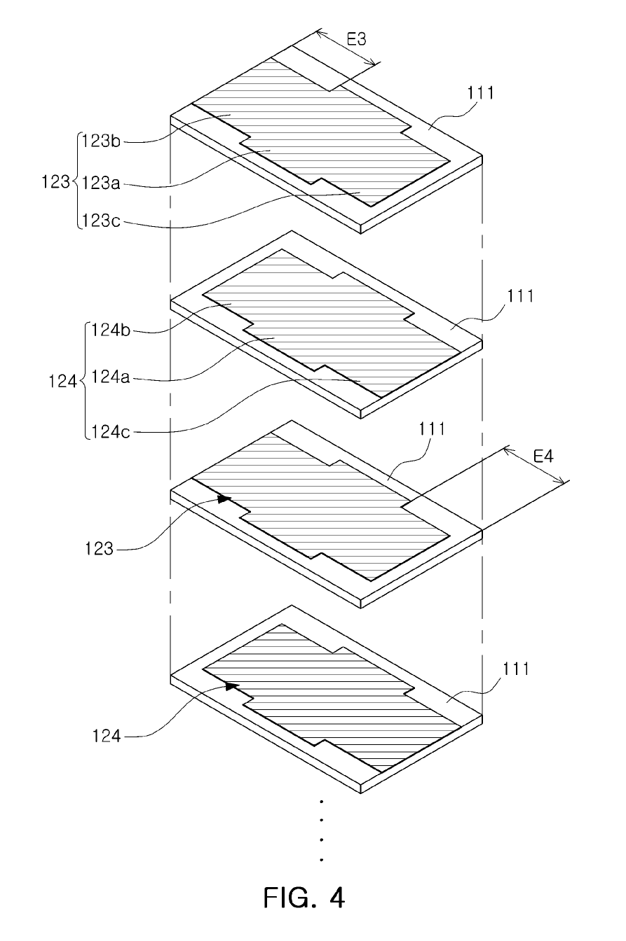

FIG. 1 is a perspective view schematically illustrating a multilayer ceramic electronic component according to an exemplary embodiment in the present disclosure; FIG. 2 is a cross-sectional view taken along line A-A′ of FIG. 1; FIG. 3 is an exploded perspective view illustrating examples of first and second internal electrodes of the multilayer ceramic electronic component of FIG. 1; and FIG. 4 is an exploded perspective view illustrating examples of third and fourth internal electrodes of the multilayer ceramic electronic component of FIG. 1.

Referring to FIGS. 1 through 4, a multilayer ceramic electronic component 100, according to the present exemplary embodiment, may include a ceramic body 110; first and second external electrodes 131 and 132; a first active part A1 including a plurality of first and second internal electrodes 121 and 122; and a second active part A2 including a plurality of third and fourth internal electrodes 123 and 124.

The ceramic body 110 may be formed by stacking a plurality of dielectric layers 111 and then sintering the stacked dielectric layers 111.

In this case, the respective adjacent dielectric layers 111 of the ceramic body 110 may be integrated with each other so that boundaries therebetween are not readily apparent.

In addition, the ceramic body 110 may have a hexahedral shape. However, a shape of the ceramic body 110 is not limited thereto.

In the present exemplary embodiment, for convenience of explanation, surfaces of the ceramic body 110 opposing each other in a thickness (T) direction in which the dielectric layers 111 of the ceramic body 110 are stacked will be defined as lower and upper surfaces 1 and 2, surfaces of the ceramic body 110 connecting the upper and lower surfaces 2 and 1 to each other and opposing each other in a length (L) direction will be defined as first and second end surfaces 3 and 4, and surfaces perpendicularly intersecting with the first and second end surfaces 3 and 4 and opposing each other in a width (W) direction will be defined as third and fourth side surfaces 5 and 6.

Meanwhile, an upper cover layer 112 having a predetermined thickness may be formed on the uppermost internal electrode of the ceramic body 110, and a lower cover layer 113 may be formed below the lowermost internal electrode of the ceramic body 110.

Here, the upper and lower cover layers 112 and 113 may be formed of the same composition as that of the dielectric layer 111 and be formed by stacking at least one or more dielectric layers that do not include internal electrodes on the uppermost internal electrode of the ceramic body 110 and below the lowermost internal electrode thereof, respectively.

The dielectric layer 111 may contain a ceramic material having high permittivity such as a BaTiO₃ based ceramic powder, or the like. However, the material of the dielectric layer 111 is not limited thereto.

The BaTiO₃-based ceramic powder may be, for example, (Ba₁₋ₓCaₓ)TiO₃, Ba (Ti_{1-y}Ca_{y})O₃, (Ba₁₋ₓCaₓ) (Ti_{1-y}Zr_{y})O_{3f} Ba(Ti_{1-y}Zr_{y})O₃ in which Ca, Zr, and the like, are partially solid-dissolved in BaTiO₃, or the like. However, an example of the BaTiO₃-based ceramic powder is not limited thereto.

In addition, at least one of ceramic additives, an organic solvent, a plasticizer, a binder, and a dispersant may be contained in the dielectric layer 111.

As the ceramic additive, for example, a transition metal oxide or carbide, rare earth elements, magnesium (Mg), aluminum (A1), or the like, may be used.

The first and second external electrodes 131 and 132 may be disposed on both end portions of the ceramic body 110 in the length direction, and include first and second body portions 131a and 132a and first and second band portions 131b and 132b, respectively.

The first and second body portions 131a and 132a may cover the first and second end surfaces 3 and 4 of the ceramic body 110 in the length direction, respectively, and be electrically connected to exposed end portions of the first and second internal electrodes 121 and 122 and the third and fourth internal electrodes 123 and 124, respectively.

The first and second band portions 131b and 132b may be portions extended from the first and second body portions 131a and 132a, respectively, to cover portions of circumferential surfaces of the ceramic body 110.

Meanwhile, plating layers (not illustrated) may be formed on the first and second external electrodes 131 and 132. The plating layers may include first and second nickel (Ni) plating layers each formed on the first and second external electrodes 131 and 132 and first and second tin (Sn) plating layers each formed on the first and second nickel plating layers, as an example.

The first active part A1 may be positioned in an upper portion of the ceramic body 110 based on a virtual line DL, and include the plurality of first and second internal electrodes 121 and 122 alternately stacked with each other. In the first active part A1, at the time of applying power thereto, maximum displacement may be generated at the first and second external electrodes 131 and 132 existing on the first and second end surfaces 3 and 4 of the ceramic body 110 in the length direction.

The second active part A2 may be positioned in a lower portion of the ceramic body 110 based on the virtual line DL, and include the plurality of third and fourth internal electrodes 123 and 124 alternately stacked with each other. In the second active part A2, at the time of applying power thereto, minimum displacement may be generated at the first and second external electrodes 131 and 132 existing on the first and second end surfaces 3 and 4 of the ceramic body 110 in the length direction. In this case, for example, the first and second active parts A1 and A2 may be formed to have the same height (thickness) as each other. Alternatively, if necessary, the first active part A1 may have a higher height or the second active part A2 may have a higher height. That is, the height of the first and second active parts A1 and A2 may be variously changed.

After the first and second internal electrodes 121 and 122 are formed on ceramic sheets forming the dielectric layer 111 and stacked, the first and second internal electrodes 121 and 122 may be alternately disposed in the ceramic body 110 in the thickness direction, with each of the dielectric layers 111 interposed therebetween by sintering.

The first and second internal electrodes 121 and 122 as described above, which are a pair of electrodes having different polarities from each other, may be disposed to face each other in a stacking direction of the dielectric layers 111, and may be electrically insulated from each other by the dielectric layer 111 disposed therebetween.

One of the ends of the first and second internal electrodes 121 and 122 may be exposed to the first and second end surfaces 3 and 4 of the ceramic body 110 in the length direction, respectively.

End portions of the first and second internal electrodes 121 and 122 alternately exposed to the first and second end surfaces 3 and 4 of the ceramic body 110 in the length direction may be electrically connected to the first and second body portions 131a and 132a of the first and second external electrodes 131 and 132 at the first and second end surfaces 3 and 4 of the ceramic body 110 in the length direction, respectively.

In addition, the first and second internal electrodes 121 and 122 may include first and second body portions 121a and 122a, and a pair of first protrusion portions 121b and 122c and a pair of second protrusion portions 122b and 122c extended from the first and second body portions 121a and 122a in the width direction and corresponding to the first and second band portions 131b and 132b of the first and second external electrodes 131 and 132 disposed on the third and fourth side surfaces 5 and 6 of the ceramic body 110 in the width direction, respectively.

Further, the first and second internal electrodes 121 and 122 may be formed of a conductive metal, for example, nickel (Ni), a nickel (Ni) alloy, or the like. However, a material of the first and second internal electrodes 121 and 122 is not limited thereto.

Through the above-mentioned configuration, when a predetermined voltage is applied to the first and second external electrodes 131 and 132, electric charge may be accumulated between the third and fourth internal electrodes 123 and 124 facing each other.

In this case, capacitance of the first active part A1 of the multilayer ceramic electronic component 100 may be in proportion to an overlapping area between the first and second internal electrodes 121 and 122 overlapping each other in the stacking direction of the dielectric layers 111.

After the third and fourth internal electrodes 123 and 124 are formed on ceramic sheets forming the dielectric layer 111 and stacked, the third and fourth internal electrodes 123 and 124 may be alternately disposed in the ceramic body 110 in the thickness direction, with each of the dielectric layers 111 interposed therebetween by sintering.

The third and fourth internal electrodes 123 and 124 as described above, which are a pair of electrodes having different polarities from each other, may be disposed to face each other in the stacking direction of the dielectric layers 111, and may be electrically insulated from each other by the dielectric layer 111 disposed therebetween.

One of the ends of the third and fourth internal electrodes 123 and 124 may be exposed to the first and second end surfaces 3 and 4 of the ceramic body 110 in the length direction, respectively.

End portions of the third and fourth internal electrodes 123 and 124 alternately exposed to the first and second end surfaces 3 and 4 of the ceramic body 110 in the length direction may be electrically connected to the first and second body portions 131a and 132a of the first and second external electrodes 131 and 132 at the first and second end surfaces 3 and 4 of the ceramic body 110 in the length direction, respectively.

In addition, the third and fourth internal electrodes 123 and 124 may include third and fourth body portions 123a and 124a, and a pair of first recess portions 123b and 123c and a pair of second recess portions 124b and 124c recessed from the third and fourth body portions 123a and 124a in the width direction and corresponding to the first and second band portions 131b and 132b of the first and second external electrodes 131 and 132 disposed on the third and fourth side surfaces 5 and 6 of the ceramic body 110 in the width direction, respectively.

The pair of first recess portions 123b and 123c of the third internal electrode 123 may overlap the pair of first protrusion portions 121b and 121c of the first internal electrode 121. The pair of second recess portions 124b and 124c of the fourth internal electrode 124 may overlap the pair of second protrusion portions 122b and 122c of the second internal electrode 122.

In this case, the third and fourth internal electrodes 123 and 124 may be formed of a conductive metal such as nickel (Ni), a nickel (Ni) alloy, or the like. However, a material of the third and fourth internal electrodes 123 and 124 is not limited thereto.

Through the above-mentioned configuration, when a predetermined voltage is applied to the first and second external electrodes 131 and 132, electric charges may be accumulated between the first and second internal electrodes 121 and 122 facing each other.

In this case, capacitance of the second active part A2 of the multilayer ceramic electronic component 100 may be in proportion to an overlapping area between the third and fourth internal electrodes 123 and 124 overlapping each other in the stacking direction of the dielectric layers 111.

In addition, a length BW of the first and second band portions 131b and 132b of the first and second external electrodes 131 and 132 may be equal to or greater than a length E1, E2, E3 or E4 of the protrusion portions of the first and second internal electrodes 121 and 122 or the recess portions of the third and fourth internal electrodes 123 and 124.

When the length BW of the first and second band portions 131b and 132b of the first and second external electrodes 131 and 132 is less than the length E1 to E4 of the protrusion portions of the first and second internal electrodes 121 and 122 or the recess portions of the third and fourth internal electrodes 123 and 124, a solder may not be formed throughout a maximized opposite phase region formed in a lower portion of the multilayer ceramic electronic component due to maximum displacement at an upper portion of the multilayer ceramic electronic component and minimum displacement at the lower portion thereof. Therefore, it may be difficult to expect an effect of reducing acoustic noise in the present exemplary embodiment, maximally utilizing an opposite phase effect.

In addition, when the length BW of the first and second band portions 131b and 132b of the first and second external electrodes 131 and 132 is less than the length E1 to E4 of the protrusion portions of the first and second internal electrodes 121 and 122 or the recess portions of the third and fourth internal electrodes 123 and 124, adhesive strength of the first and second external electrodes 131 and 132 may be reduced, such that the capacitor may be easily separated by external impacts.

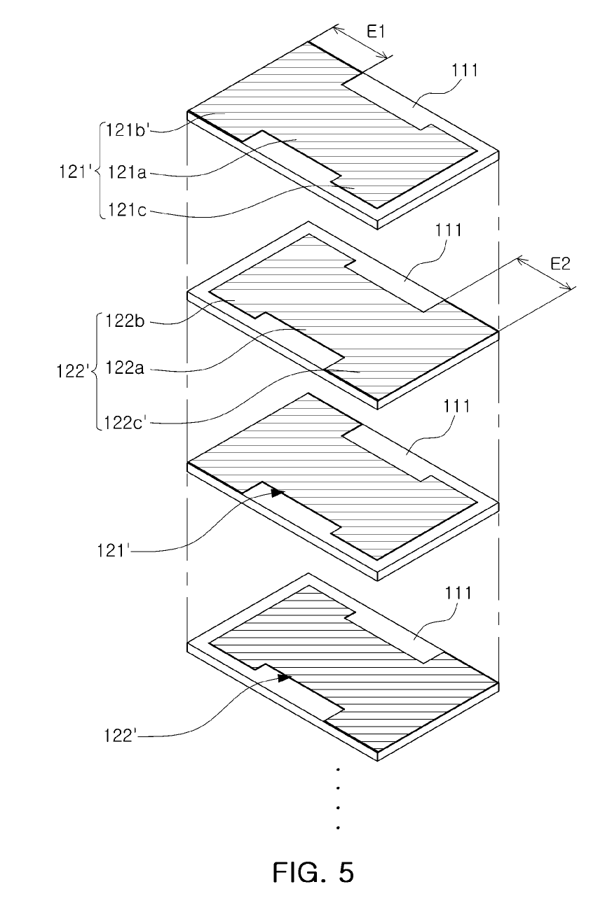

FIG. 5 is an exploded perspective view illustrating other examples of the first and second internal electrodes of the multilayer ceramic electronic component of FIG. 1.

Referring to FIG. 5, a first protrusion portion 121b′ of the first internal electrode 121′ exposed to the first end surface 3 of the ceramic body 110 in the length direction and a second protrusion portion 122c′ of a second internal electrode 122′ exposed to the second end surface 4 of the ceramic body 110 in the length direction may be extended and exposed in a width direction of the dielectric layer 111, respectively, so as to come in contact with portions of the first and second band portions 131b and 132b disposed on the third and fourth side surfaces 5 and 6 of the ceramic body 110 in the width direction.

Due to this structure, margin portions in the width direction of the ceramic body 110 may be reduced, such that step portions may be reduced. In addition, a contact area between the internal electrodes and the external electrodes may be increased, thereby improving electric connectivity between the electrodes.

### Modified Exemplary Embodiment

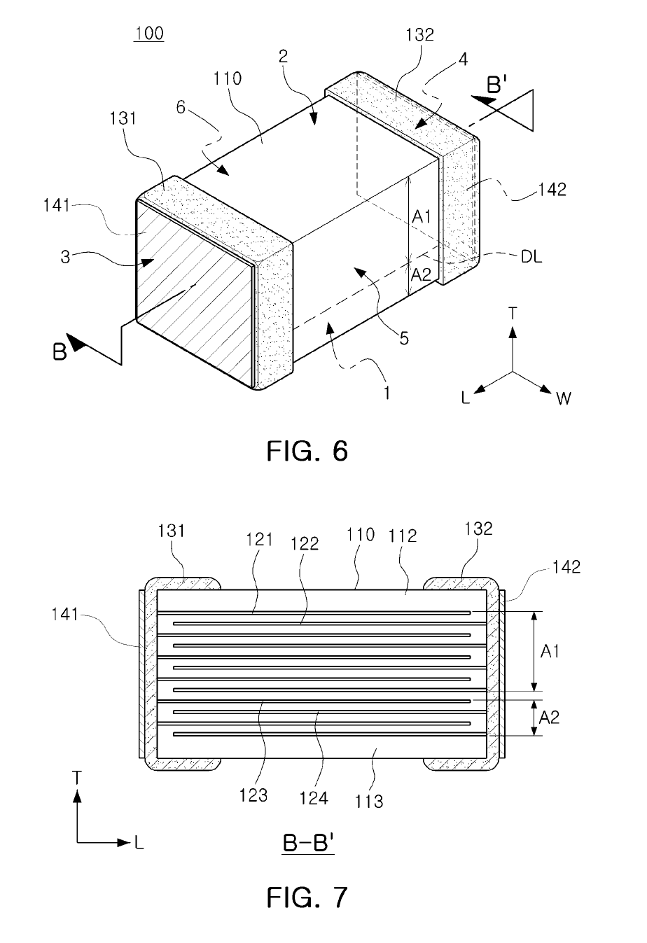

FIG. 6 is a perspective view illustrating a structure in which an insulating layer is disposed in the multilayer ceramic electronic component of FIG. 1; and FIG. 7 is a cross-sectional view taken along line B-B′ of FIG. 6.

Here, since structures of a ceramic body 110, first and second external electrodes 131 and 132, first and second internal electrodes 121 and 122, and third and fourth internal electrodes 123 and 124 of the multilayer ceramic electronic component are similar to those in the above-mentioned exemplary embodiment, a detailed description thereof will be omitted in order to avoid an overlapping description; however, a modified structure as compared to the above-mentioned exemplary embodiment will be described in detail.

Referring to FIGS. 6 and 7, in the multilayer ceramic electronic component 100, according to the present exemplary embodiment, first and second insulating layers 141 and 142 may be further disposed on first and second body portions 131a and 132a of the first and second external electrodes 131 and 132.

The first and second insulating layers 141 and 142 as described above may be formed of an insulating material such as an epoxy, or the like, and may prevent solder from being formed on the first and second body portions 131a and 132a of the first and second external electrodes 131 and 132 at the time of mounting the multilayer ceramic electronic component on a board, such that the solder may be intensively formed on surfaces of the first and second external electrodes 131 and 132 in a length-width (L-W) direction of the ceramic body 110, thereby further improving the effect of reducing acoustic noise by the opposite phase.

In other words, at the time of mounting the multilayer ceramic electronic component on a board, a solder does not remain on surfaces of the first and second external electrodes 131 and 132 in a width-thickness (W-T) direction of the ceramic body 110 but is formed to have a high height on the surfaces of the first and second external electrodes 131 and 132 in the L-W direction thereof while intensively flowing to the surfaces thereof in the L-W direction thereof, such that the solder may be uniformly distributed throughout the upper and lower portions of the ceramic body 110 of which displacement shapes are opposite each other, which may significantly increase an offset effect of the constant phase/opposite phase, thereby improving the effect of reducing acoustic noise of the multilayer ceramic electronic component.

The insulating material such as the epoxy, or the like, may be applied on the first and second body portions 131a and 132a of the first and second external electrodes 131 and 132 by a dipping method or various printing methods. However, a method of forming the first and second insulating layers according to the present disclosure is not limited thereto. In addition, after an application process, a heat treatment process may be performed, such that the applied insulating material may be cured.

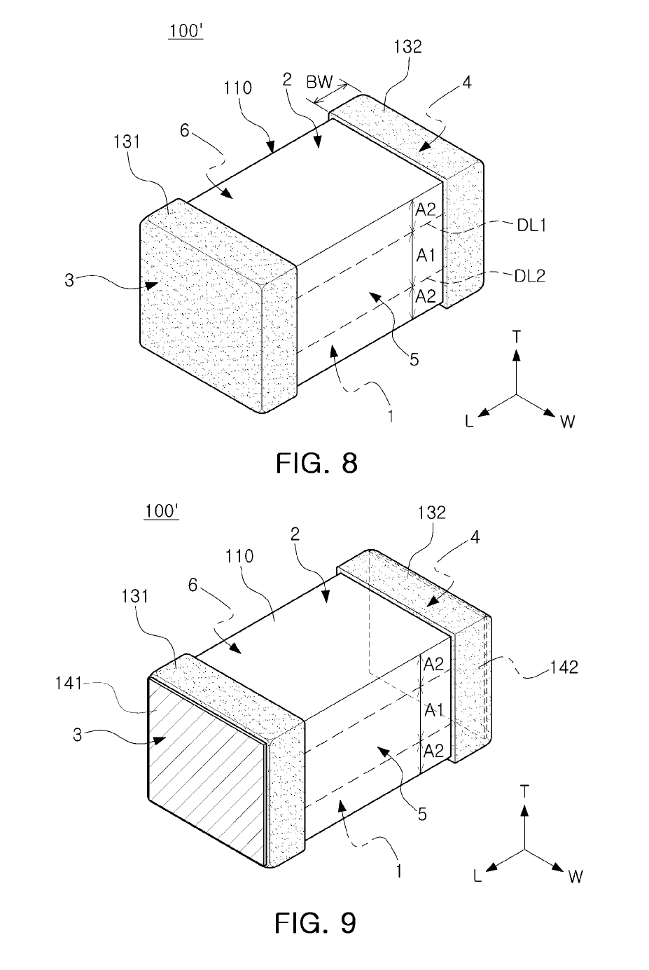

FIG. 8 is a perspective view schematically illustrating a multilayer ceramic electronic component 100′ according to another exemplary embodiment.

Here, since structures of a ceramic body 110, first and second external electrodes 131 and 132, first and second internal electrodes 121 and 122, and third and fourth internal electrodes 123 and 124 of the multilayer ceramic electronic component 100′ are similar to those in the above-mentioned exemplary embodiment, a detailed description thereof will be omitted in order to avoid an overlapping description; however, a modified structure as compared to the above-mentioned exemplary embodiment will be described in detail.

Referring to FIG. 8, in the multilayer ceramic electronic component 100′, according to the present exemplary embodiment, a lower second active part A2 may be disposed in a lowermost portion thereof, a first active part A1 may be disposed on a lower second active part A2 based on a virtual line DL2, and an upper second active part A2 may be disposed on the first active part A1 based on a virtual line DLL

In this case, when the upper and lower second active parts A2 are of the same thickness, directionality of the electronic component may be removed, whereby defects caused by mounting the multilayer ceramic electronic component in an opposite direction may be prevented.

Meanwhile, although not illustrated, in a multilayer ceramic electronic component according to the present inventive concept, for example, a plurality of first and second active parts may be further disposed alternately with each other in the thickness direction.

Further, referring to FIG. 9, in the multilayer ceramic electronic component 100′, according to the present exemplary embodiment, insulating layers 141 and 142 may be further disposed on first and second body portions 131a and 132a of the first and second external electrodes 131 and 132.

Here, since the structure is similar to that in the above-mentioned exemplary embodiment, a detailed description thereof will be omitted in order to avoid an overlapping description.

### Board Having Multilayer Ceramic Electronic Component

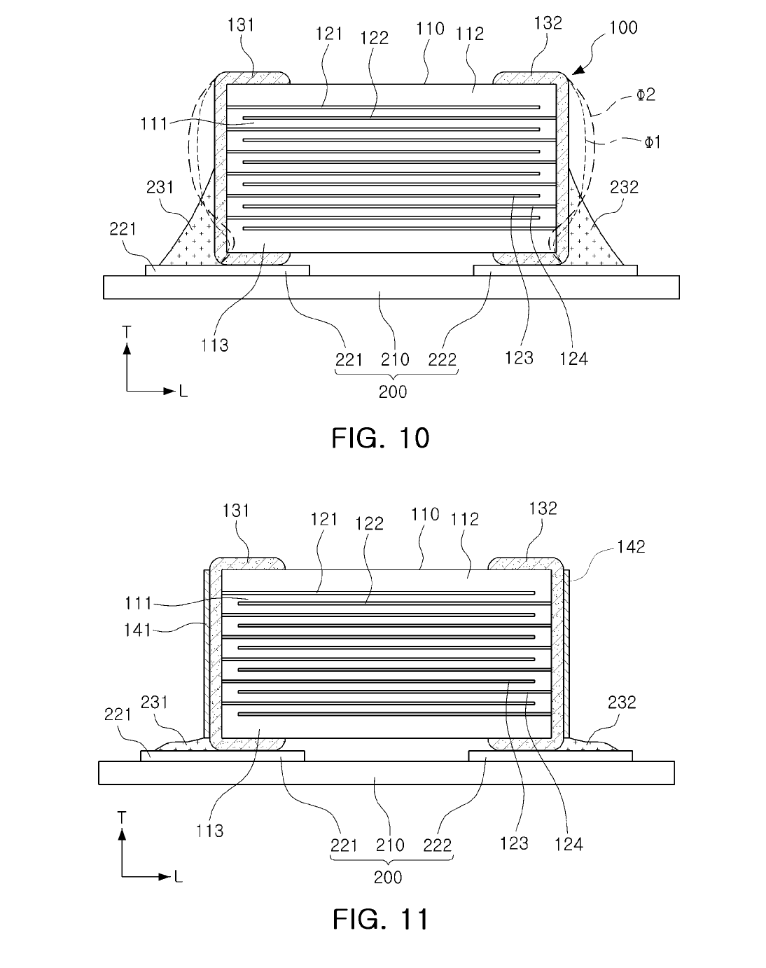

FIG. 10 is a cross-sectional view illustrating a board in which the multilayer ceramic electronic component of FIG. 1 is mounted on a circuit board.

Referring to FIG. 10, aboard 200 having the multilayer ceramic electronic component 100, according to an exemplary embodiment, may include a circuit board 210 on which the multilayered ceramic electronic component 100 is horizontally mounted, and the first and second electrode pads 221 and 222 formed on an upper surface of the circuit board 210 to be spaced apart from each other.

In this case, the multilayer ceramic electronic component 100 may be connected to the circuit board 210 by solders 231 and 232, or the like, in a state in which lower surfaces of the first and second band portions 131b and 132b of the first and second external electrodes 131 and 132 are positioned to contact the first and second electrode pads 221 and 222, respectively.

When voltage is applied in a state in which the multilayer ceramic electronic component 100 is mounted on the circuit board 210 as described above, acoustic noise may be generated.

Here, sizes of the first and second electrode pads 221 and 222 may be an indicator for determining an amounts of solder 231 and 232 connecting the first and second external electrodes 131 and 132 of the multilayer ceramic electronic component 100 to the first and second electrode pads 221 and 222, and the level of acoustic noise may be adjusted depending on the amount of the solders 231 and 232.

According to the present exemplary embodiment, when voltages having different polarities are applied to the first and second external electrodes 131 and 132 formed on the first and second end surfaces of the ceramic body 110 in the length direction in a state in which the multilayer ceramic electronic component 100 is mounted on the circuit board 210, the ceramic body 110 may be expanded and contracted in the thickness direction due to an inverse piezoelectric effect of the dielectric layers 111, and the first and second end surfaces of the ceramic body 110 in the length direction on which the first and second external electrodes 131 and 132 are formed may be contracted and expanded as opposed to the expansion and the contraction of the ceramic body 110 in the thickness direction due to a Poisson effect.

Here, the pair of first recess portions 123b and 123c and the pair of second recess portions 124b and 124c of the third and fourth internal electrodes 123 and 124 in the second active part A2 may overlap the pair of first protrusion portions 121b and 121c and the pair of second protrusion portions 122b and 122c of the first and second internal electrodes 121 and 122 in the first active part A1, respectively.

Due to the configuration as described above, piezoelectric stress of the first active part A1 transferred from surfaces of the ceramic body 110 in the L-T direction to the third and fourth side surfaces 5 and 6 of the ceramic body 110 in the width direction may be relatively greater than that of the second active part A2.

Therefore, an opposite phase φ₂ having a relatively larger size than an opposite phase φ₁ of a multilayer ceramic electronic component according to the related art having the same internal electrode structure may be formed in the entire active part by a difference in piezoelectric stress between upper and lower portions of the surfaces of the ceramic body 110 in the L-W direction. Here, φ1 indicates vibration displacement of a general multilayer ceramic electronic component according to the related art in the thickness direction thereof, and φ2 indicates an increase in vibration displacement of a multilayer ceramic electronic component having an inventive structure according to the exemplary embodiment.

Therefore, the solder may be intensively distributed toward the third and fourth side surfaces 5 and 6 of the ceramic body 110 in the width direction to thereby be highly formed by the insulating layers 141 and 142 formed on the first and second end surfaces 3 and 4 of the ceramic body 110 in the length direction.

Therefore, the constant phase and the opposite phase of the upper and lower portions of the ceramic body 110 may be uniformly distributed to the solder to thereby offset each other, such that vibrations transferred through the solder may be reduced, thereby improving the effect of reducing acoustic noise of the multilayer ceramic electronic component.

In this case, heights of the first active part A1 and the second active part A2 may be flexibly adjusted in consideration of heights of the solders 231 and 232 changed depending on the first and second electrode pads 221 and 222.

Meanwhile, FIG. 11 is a view illustrating a board in which the multilayer ceramic electronic component, according to another exemplary embodiment, is mounted on a circuit board. Here, since the board has a structure similar to that of the board according to the previous exemplary embodiment, except that the multilayer ceramic electronic component 100 includes the first and second insulating layers 141 and 142, a detailed description thereof will be omitted.

In the case of the structure illustrated in FIG. 11, the first and second insulating layers 141 and 142 may be formed of an insulating material such as an epoxy, or the like, and at the time of mounting the multilayer ceramic electronic component on the circuit board, solder may not be formed on the first and second body portions 131a and 132b of the first and second external electrodes, such that the solder may be heavily formed on surfaces of the first and second external electrodes in the L-W directions.

Therefore, acoustic noise may be further reduced by allowing vibrations in the surfaces of the ceramic body 110 in the W-T direction thereof not to be transferred to the board through the solder, such that acoustic noise may be reduced while an existing electrode pad structure is not changed but is used as it is.

Further, volume of the solder formed on circumferential surfaces of the first and second external electrodes may be reduced, such that even in the case of mounting a plurality of multilayer ceramic electronic components on a board at a narrow pitch, that is, in the case of high-density mounting of the plurality of multilayer ceramic electronic components on the circuit board, a solder bridge may not be formed between each of the multilayer ceramic electronic components, thereby improving reliability of the component.

As set forth above, according to exemplary embodiments, piezoelectric displacement may be maximized in the first active parts disposed at the upper portion of the ceramic body, and piezoelectric displacement may be minimized in the second active part positioned to be adjacent to the mounting surface. Therefore, the opposite phase having a relatively larger size than that of the multilayer ceramic electronic component, according to the related art, may be formed through the second active part and a lower cover layer below the second active part by excessive displacement formed in the first active part. Accordingly, formation of the opposite phase in the portions on which the solders are mounted may be significantly increased, such that the constant phase at the upper portion of the multilayer ceramic electronic component and the opposite phase at the lower portion thereof may offset each other, thereby reducing acoustic noise of the multilayer ceramic electronic component.

While exemplary embodiments have been shown and described above, it will be apparent to those skilled in the art that modifications and variations could be made without departing from the scope of the present invention as defined by the appended claims.

What is claimed is:

1. A multilayer ceramic electronic component comprising:
a ceramic body including a plurality of dielectric layers which are stacked therein, and first and second active parts; and
first and second external electrodes respectively disposed on both end portions of the ceramic body and respectively including band portions which extend to cover portions of circumferential surfaces of the ceramic body;
wherein the first active part includes a plurality of first and second internal electrodes alternately exposed to respective end surfaces of the ceramic body in a length direction thereof and including protrusion portions which correspond to the band portions of the first and second external electrodes and extend in a width direction of the ceramic body, and
the second active part is positioned below the first active part in the ceramic body and includes a plurality of third and fourth internal electrodes alternately exposed to both end surfaces of the ceramic body in the length direction and including recess portions which correspond to the band portions of the first and second external electrodes and are recessed in the width direction of the ceramic body.

2. The multilayer ceramic electronic component of claim 1, wherein the second active part is further disposed on the first active part.

3. The multilayer ceramic electronic component of claim 1, wherein a plurality of first and second active parts are alternately disposed in a thickness direction of the ceramic body.

4. The multilayer ceramic electronic component of claim 1, wherein a length of the band portions of the first and second external electrodes is equal to or greater than that of the protrusion portions of the first and second internal electrodes.

5. The multilayer ceramic electronic component of claim 1, wherein a length of the band portions of the first and second external electrodes is equal to or greater than that of the recess portions of the third and fourth internal electrodes.

6. The multilayer ceramic electronic component of claim 1, wherein the protrusion portions of the first and second internal electrodes are exposed to both side surfaces of the ceramic body in the width direction.

7. The multilayer ceramic electronic component of claim 1, further comprising insulating layers disposed on body portions of the first and second external electrodes, respectively.

8. A board having a multilayer ceramic electronic component, the board comprising:
a circuit board on which a plurality of electrode pads are provided; and
a multilayer ceramic electronic component mounted on the circuit board,
wherein the multilayer ceramic electronic component comprises:
a ceramic body including a plurality of dielectric layers which are stacked therein, and first and second active parts; and
first and second external electrodes respectively disposed on both end portions of the ceramic body and respectively including band portions which extend to cover portions of circumferential surfaces of the ceramic body;
wherein the first active part includes a plurality of first and second internal electrodes alternately exposed to respective end surfaces of the ceramic body in a length direction and including protrusion portions which correspond to the band portions of the first and second external electrodes and extend in a width direction of the ceramic body,
the second active part is positioned below the first active part in the ceramic body and includes a plurality of third and fourth internal electrodes alternately exposed to both end surfaces of the ceramic body in the length direction and including recess portions which correspond to the band portions of the first and second external electrodes and are recessed in the width direction of the ceramic body, and
lower surfaces of the band portions of the first and second external electrodes are connected to the electrode pads.

9. The board of claim 8, wherein the second active part is further disposed on the first active part.

10. The board of claim 8, wherein a plurality of first and second active parts are alternately disposed in a thickness direction of the ceramic body.

11. The board of claim 8, wherein a length of the band portions of the first and second external electrodes is equal to or greater than that of the protrusion portions of the first and second internal electrodes.

12. The board of claim 8, wherein a length of the band portions of the first and second external electrodes is equal to or greater than that of the recess portions of the third and fourth internal electrodes.

13. The board of claim 8, wherein the protrusion portions of the first and second internal electrodes are exposed to both side surfaces of the ceramic body in the width direction.

14. The board of claim 8, wherein the multilayer ceramic electronic component further includes insulating layers disposed on body portions of the first and second external electrodes, respectively.
